(19) United States
(12) Patent Application Publication
(10) Pub. No.: US 2019/0191565 A1
(43) Pub. Date: Jun. 20, 2019

(54) ELECTRONIC DEVICE AND MULTILAYER CERAMIC SUBSTRATE

(71) Applicant: Murata Manufacturing Co., Ltd., Nagaokakyo-shi (JP)

(72) Inventors: Takahiro Oka, Nagaokakyo-shi (JP); Yuki Takemori, Nagaokakyo-shi (JP); Kazuo Kishida, Nagaokakyo-shi (JP); Hiromichi Kawakami, Nagaokakyo-shi (JP); Yukio Yamamoto, Nagaokakyo-shi (JP); Kensuke Otake, Nagaokakyo-shi (JP)

(21) Appl. No.: 16/283,858

(22) Filed: Feb. 25, 2019

Related U.S. Application Data
(63) Continuation of application No. PCT/JP2017/023542, filed on Jun. 27, 2017.

(30) Foreign Application Priority Data
Aug. 30, 2016 (JP) 2016-168314

(51) Int. Cl. H05K 1/18; H01L 23/13; H01L 23/15; H01L 23/498; H05K 1/11; H05K 1/03; H05K 3/34

(52) U.S. Cl. CPC H05K 1/181; H01L 23/13; H01L 23/15; H01L 24/16; H05K 1/111; H05K 1/0306; H05K 3/3436; H01L 23/49822

(57) ABSTRACT

An electronic device that includes an electronic component mounted on a multilayer ceramic substrate. The electronic component includes a connection terminal on the mounting surface side thereof, the connection terminal having an end with a rounded convex shape when viewed in cross section. The multilayer ceramic substrate includes a recessed portion at a position corresponding to the connection terminal, the recessed portion having a rounded concave shape when viewed in cross section, and a surface electrode disposed on at least part of the recessed portion and electrically connected to the connection terminal.

### CROSS REFERENCE TO RELATED APPLICATIONS

The present application is a continuation of International application No. PCT/JP2017/023542, filed Jun. 27, 2017, which claims priority to Japanese Patent Application No. 2016-168314, filed Aug. 30, 2016, the entire contents of each of which are incorporated herein by reference.

### FIELD OF THE INVENTION

The present invention relates to an electronic device including an electronic component mounted on a multilayer ceramic substrate. The present invention also relates to a multilayer ceramic substrate used for the mounting of an electronic component.

### BACKGROUND OF THE INVENTION

Patent Document 1 substantially discloses a method for mounting an electronic component on a substrate. The electronic component includes bump electrodes and positioning protrusions having a greater height than the bump electrodes. The substrate includes recessed portions having inclined surfaces corresponding to positions of the positioning protrusions, each recessed portion having a bottom provided with an electrode. When the positioning protrusions are engaged and pressed against the recessed portions, the positioning protrusions are thus deformed. The structure described above seemingly enables the avoidance of a reduction in reliability due to misalignment in mounting (connecting) the electronic component on a narrow-pitch or fine-line substrate.

PTL 1: Japanese Patent No. 4889464

### SUMMARY OF THE INVENTION

In the method for mounting an electronic component described in Patent Document 1, the substrate has the recessed portions on the surface thereof in order to match the height of the positioning protrusions to the height of other bump electrodes in a mounted state. In addition to the positioning protrusions, if an electronic component including connection terminals having different heights is mounted on a substrate, the substrate including the recessed portions on a surface thereof can be used.

However, when connection terminals such as solder bumps or copper pillar bumps are brought into contact with surface electrodes disposed on the recessed portions on the surface of the substrate in order to mount an electronic component on the substrate, the electronic component may be heavily damaged to cause defective contact.

The present invention has been made in order to solve the foregoing problems. It is an object of the present invention to provide an electronic device including an electronic component mounted on a multilayer ceramic substrate, in which damage to the electronic component during mounting and the occurrence of the defective contact can be reduced. It is another object of the present invention to provide a multilayer ceramic substrate that can reduce damage to an electronic component during mounting.

An electronic device according to an aspect of the present invention includes an electronic component mounted on a multilayer ceramic substrate. The electronic component includes a connection terminal on the mounting surface side, the connection terminal having an end with a rounded convex shape when viewed in cross section. The multilayer ceramic substrate includes a recessed portion at a position corresponding to the connection terminal, the recessed portion having a round shape when viewed in cross section, and a surface electrode disposed on at least part of the recessed portion and electrically connected to the connection terminal.

The electronic device according to the present invention includes the round-shaped recessed portion at the position on the surface of the substrate corresponding to the round-shaped connection terminal, and the surface electrode on at least part of the recessed portion. If a recessed portion has a flat bottom as in the related art, a connection terminal and a surface electrode come into point contact with each other during the mounting of an electronic component on a multilayer ceramic substrate and are greatly stressed. In contrast, in this electronic device according to the present invention, the connection terminal and the surface electrode can come into surface contact with each other during the mounting of the electronic component on the multilayer ceramic substrate. This results in a low stress, compared with when the connection terminal and the surface electrode come into point contact with each other. It is thus possible to reduce damage to the electronic component and reduce the occurrence of defective contact.

In the electronic component according to the present invention, the recessed portion preferably has an arc- or bathtub-like shape in cross section. In this case, the connection terminal and the surface electrode easily come into surface contact with each other, thus further reducing damage to the electronic component.

In the electronic component according to the present invention, letting the radius of curvature of the recessed portion when viewed in cross section be Rs, and letting the radius of curvature of the connection terminal when viewed in cross section be Rp, the value of Rp/Rs is preferably 0.1 to 1.0. In this case, the occurrence of the defective contact can be further reduced.

According to the present invention, a multilayer ceramic substrate on which an electronic component is to be mounted includes a recessed portion at a position on a mounting surface of the multilayer ceramic substrate, the recessed portion having a round shape when viewed in cross section, and a surface electrode disposed on at least part of the recessed portion.

The multilayer ceramic substrate according to the present invention includes the round-shaped recessed portion and a surface electrode on at least part of the recessed portion. When a connection terminal of an electronic component has an end with a rounded convex shape, the connection terminal and the surface electrode can come into surface contact with each other. This results in a low stress, compared with when they come into point contact with each other. It is thus possible to reduce damage to the electronic component and reduce the occurrence of the defective contact.

In the multilayer ceramic substrate according to the present invention, the recessed portion preferably has an arc- or bathtub-like shape in cross section. In this case, the connection terminal and the surface electrode easily come into surface contact with each other, thus further reducing damage to the electronic component.

According to the present invention, it is possible to provide the electronic device including the electronic component mounted on the multilayer ceramic substrate, in which damage to the electronic component during mounting and the occurrence of the defective contact can be reduced.

### BRIEF DESCRIPTION OF THE DRAWINGS

FIG. 1 is a schematic cross-sectional view illustrating an example of an electronic device according to the present invention.

FIG. 2(a) is a schematic cross-sectional view illustrating a copper pillar bump as an example of a connection terminal, and FIG. 2(b) is a schematic cross-sectional view illustrating a solder bump as another example of the connection terminal.

FIG. 3 is a schematic cross-sectional view illustrating a method for determining the radius of curvature of a copper pillar bump.

FIGS. 4(a), 4(b), 4(c), 4(d), and 4(e) are schematic cross-sectional views illustrating examples of the cross-sectional shape of a recessed portion.

FIG. 5 is a schematic cross-sectional view illustrating a method for determining the radius of curvature of a recessed portion having a bathtub-like shape in cross section.

FIGS. 6(a) and 6(b) are schematic cross-sectional views illustrating examples of a surface electrode disposed on a recessed portion.

FIGS. 7(a) and 7(b) are schematic cross-sectional views illustrating other examples of the electronic device according to the present invention.

FIGS. 8(a), 8(b), 8(c), 8(d), and 8(e) are schematic cross-sectional views illustrating an example of a method for producing the electronic device illustrated in FIG. 1.

FIGS. 9(a), 9(b), 9(c), and 9(d) are schematic cross-sectional views of illustrating positions where electronic components are mounted on multilayer ceramic substrates of Example 1, Example 2, Comparative example 1, and Comparative example 2, respectively.

### DETAILED DESCRIPTION OF THE PREFERRED EMBODIMENTS

An electronic device according to the present invention will be described below.

However, the present invention is not limited to the following configuration. Various modifications may be appropriately made within the scope of the present invention. A combination of two or more of individual preferred embodiments of the present invention described below is also included in the present invention.

FIG. 1 is a schematic cross-sectional view illustrating an example of an electronic device according to the present invention.

When the term “cross section” is simply described in this specification, the term indicates a cross section of a multilayer ceramic substrate in the thickness direction.

The entire structure is not illustrated in FIG. 1. In an electronic device 1, an electronic component 20 is mounted on a multilayer ceramic substrate 10. The electronic component 20 includes a connection terminal 21 on the mounting surface side thereof. The connection terminal 21 has an end with a rounded convex shape when viewed in cross section on the mounting surface side thereof. The multilayer ceramic substrate 10 includes a surface electrode 11 to be connected to the connection terminal 21. The multilayer ceramic substrate 10 includes a recessed portion 12 at a position on the mounting surface of the multilayer ceramic substrate corresponding to the connection terminal 21. The recessed portion 12 has a rounded concave shape when viewed in cross section. The surface electrode 11 is disposed on at least part of the recessed portion 12. The surface electrode 11 and the connection terminal 21 are electrically connected. As illustrated in FIG. 1, the surface electrode 11 also has a rounded concave shape when viewed in cross section.

Examples of the electronic component included in the electronic device according to the present invention include active components, passive components, and composites thereof. Examples of the active components include semiconductor components such as transistors, diodes, ICs, and LSIs. Examples of the passive components include chip components such as resistors, capacitors, and inductors, resonators, filters.

In the electronic device according to the present invention, the electronic component includes the connection terminal having an end with a rounded convex shape when viewed in cross section on the mounting surface side thereof. For example, in the case where the electronic component is formed of a semiconductor element such as an IC, a bump such as a copper pillar bump or a solder bump corresponds to the connection terminal. In the case where the electronic component is formed of a chip component such as a capacitor, an outer electrode corresponds to the connection terminal.

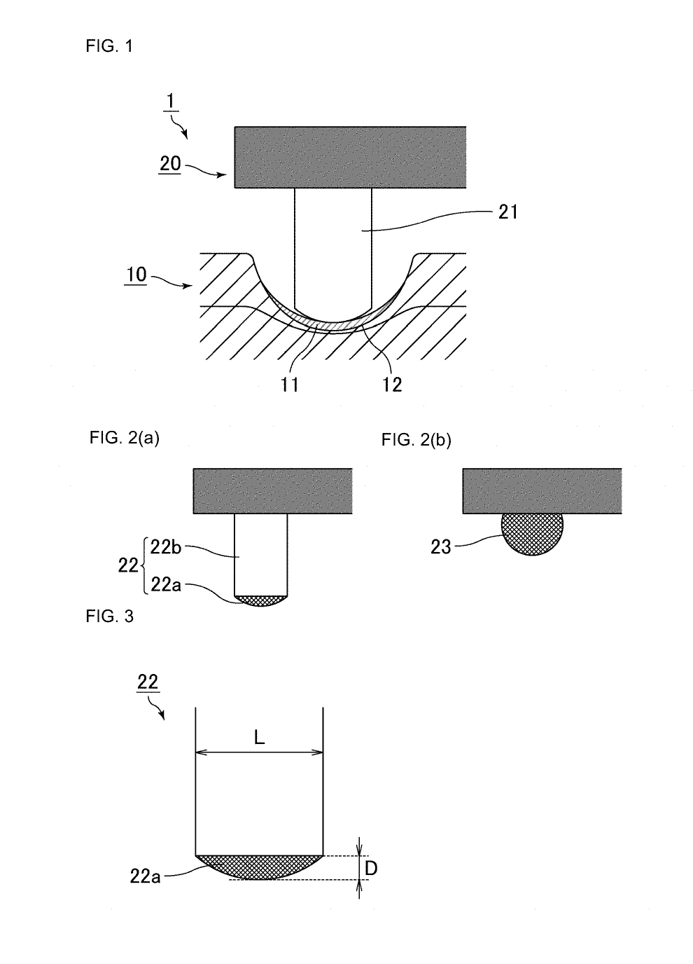

FIG. 2(a) is a schematic cross-sectional view illustrating a copper pillar bump as an example of a connection terminal. FIG. 2(b) is a schematic cross-sectional view illustrating a solder bump as another example of the connection terminal.

In a copper pillar bump 22 illustrated in FIG. 2(a), solder 22a is disposed on the tip of a pillar (post) 22b composed of copper. The tip has a rounded shape. A solder bump 23 illustrated in FIG. 2(b) has a rounded shape as a whole.

In the electronic device according to the present invention, the radius of curvature Rp of the connection terminal when viewed in cross section is not particularly limited as long as the connection terminal has an end with a rounded convex shape when viewed in cross section.

For example, in the case where the connection terminal is formed of a solder bump, the radius when the cross-sectional shape of the solder bump is regarded as a circle is denoted as Rp. In the case where the connection terminal is formed of a copper pillar bump, the radius when the cross-sectional shape of solder disposed on the tip is regarded as part of an arc is denoted as Rp.

FIG. 3 is a schematic cross-sectional view illustrating a method for determining the radius of curvature of a copper pillar bump.

In the case where the cross-sectional shape of the solder 22a disposed on the tip of the copper pillar bump 22 is regarded as part of an arc, the radius of curvature Rp can be determined by measuring the chord length (length indicated by L in FIG. 3) and the camber height (length indicated by D in FIG. 3) and using the following equation:

Rp=(L²+4D²)/8D

When the chord length L is not constant, for example, when the copper pillar bump has a racetrack shape in plan, the radius of curvature Rp may be determined by using the length of the shortest portion as the chord length L.

The multilayer ceramic substrate included in the electronic device according to the present invention includes a ceramic body having a ceramic layer on a surface thereof and a surface electrode disposed on one main surface of the ceramic body.

The ceramic body included in the multilayer ceramic substrate has a laminated structure in which ceramic layers are laminated. The ceramic body includes an inner layer conductor and a via conductor therein. The ceramic body may also include a surface electrode on the other main surface thereof.

The ceramic layer included in the ceramic body preferably contains a low-temperature co-fired ceramic material. The low-temperature co-fired ceramic material refers to, among ceramic materials, a material that can be sintered at a firing temperature of 1,000° C. or lower and that can be co-fired with, for example, silver or copper.

Examples of the low-temperature co-fired ceramic material contained in the ceramic layer include a glass composite-based low-temperature co-fired ceramic material containing a mixture of a borosilicate glass and a ceramic material such as quartz, alumina, or forsterite; a crystallized glass-based low-temperature co-fired ceramic material containing a ZnO—MgO—Al₂O₃—SiO₂-based crystallized glass; and a non-glass-based low-temperature co-fired ceramic material containing a BaO—Al₂O₃—SiO₂-based ceramic material or an Al₂O₃—CaO—SiO₂—MgO—B₂O₃-based ceramic material.

Each of the inner layer conductor and the via conductor disposed in the ceramic body preferably contains at least one conductive material selected from gold, silver, and copper, more preferably contains silver or copper. Because gold, silver, and copper have low resistance, in particular, they are suitable when the multilayer ceramic substrate is used for high-frequency applications.

The surface electrode disposed on the one main surface of the ceramic body is to be connected to the connection terminal of the electronic component and preferably contains at least one conductive material selected from gold, silver, and copper, more preferably contains silver or copper.

The surface electrode may have a single-layer structure or a multilayer structure. In the case where the surface electrode has a multilayer structure, the surface electrode preferably includes a sintered layer disposed on the ceramic layer constituting the one main surface of the ceramic body and a layer of plating disposed on the upper surface of the sintered layer. The sintered layer may be formed of a single layer alone or two or more layers. The layer of plating may be formed of a single layer or two or more layers.

The sintered layer is formed by baking a conductive paste. The layer of plating is formed by forming the sintered layer and then performing electroplating or electroless plating.

The maximum thickness of the surface electrode is preferably, but not necessarily, 2 μm to 20 μm.

In the electronic device according to the present invention, the structure of the multilayer ceramic substrate is not particularly limited. For example, the number of ceramic layers laminated and the arrangement of the surface electrode, the inner layer conductor, and the via conductor may be variously changed.

A constraining layer containing a metal oxide that is not substantially sintered at the sintering temperature of the low-temperature co-fired ceramic material may be disposed between the ceramic layers containing the low-temperature co-fired ceramic material.

Examples of the metal oxide that is not substantially sintered at the sintering temperature of the low-temperature co-fired ceramic material include alumina, titania, zirconia, silica, and magnesia. Among these, alumina or silica is preferred. These metal oxides may be used alone or in combination two or more thereof.

In the electronic device according to the present invention, the recessed portion having a rounded concave shape when viewed in cross section is disposed at a position on the mounting surface of the multilayer ceramic substrate corresponding to the connection terminal. The surface electrode is disposed on at least part of the recessed portion. The surface electrode and the connection terminal are electrically connected to each other.

In the electronic device according to the present invention, the cross-sectional shape of the recessed portion is not particularly limited as long as the recessed portion has a rounded concave shape when viewed in cross section. Preferably, the cross-sectional shape is an arc- or bathtub-like shape.

The cross-sectional shape of the recessed portion refers to a cross-sectional shape of a portion including the surface electrode. However, in the case where the surface electrode includes a layer of plating, the cross-sectional shape refers to a portion excluding the layer of plating. Thus, in the electronic device according to the present invention, the surface electrode excluding the layer of plating has a rounded concave shape when viewed in cross section.

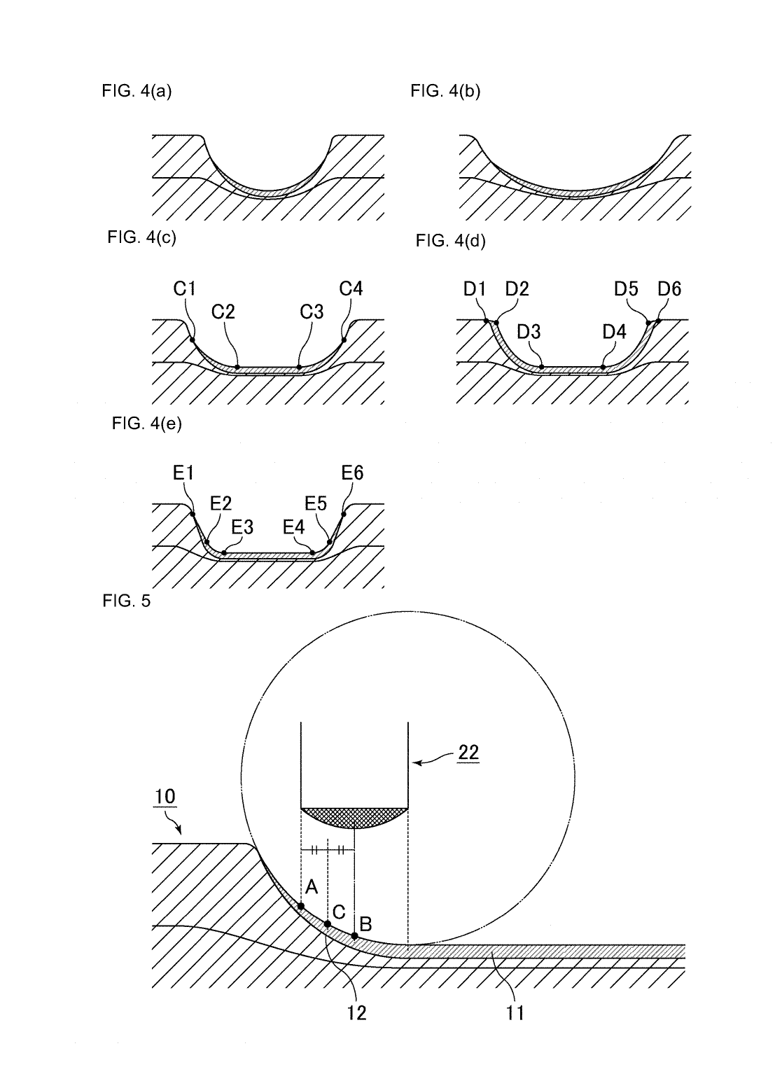

FIGS. 4(a), 4(b), 4(c), 4(d), and 4(e) are schematic cross-sectional views illustrating the cross-sectional shape of the recessed portion.

Examples of the cross-sectional shape of the recessed portion include an arc-like shape as illustrated in FIG. 4(a), an elliptical-arc-like shape as illustrated in FIG. 4(b), and bathtub-like shapes as illustrated in FIGS. 4(c), 4(d), and 4(e). The bathtub-like shape refers to a rounded concave shape having a linear base when viewed in cross section. In FIG. 4(c), a region extending from C1 to C2 has an arc-like shape. A region extending from C2 to C3 has a linear shape. A region extending from C3 to C4 has an arc-like shape. In FIG. 4(d), a region extending from D1 to D3 has a curved shape. A region extending from D3 to D4 has a linear shape. A region extending from D4 to D6 has a curved shape. Points D2 and D5 are inflection points. In FIG. 4(e), a region extending from E1 to E2 has a linear shape. A region extending from E2 to E3 has an arc-like shape. A region extending from E3 to E4 has a linear shape. A region extending from E4 to E5 has an arc-like shape. A region extending from E5 to E6 has a linear shape.

In the electronic device according to the present invention, the radius of curvature Rs of the recessed portion when viewed in cross section is not particularly limited as long as the recessed portion has a rounded concave shape when viewed in cross section.

For example, in the case where the recessed portion has an arc-like shape in cross section, the radius thereof is defined as the radius of curvature Rs. In the case where the recessed portion has an elliptical- or bathtub-like shape, the radius of a portion in contact with the connection terminal is defined as the radius of curvature Rs.

FIG. 5 is a schematic cross-sectional view illustrating a method for determining the radius of curvature of a recessed portion having a bathtub-like shape in cross section.

As illustrated in FIG. 5, in the recessed portion 12 of the multilayer ceramic substrate 10, the coordinates of position A corresponding to an end portion of the copper pillar bump 22, position B corresponding to the center of the copper pillar bump 22, and position C corresponding to the midpoint between the end portion and the center are determined. The radius of a circle passing through the three points is defined as the radius of curvature Rs. Position A is located adjacent to the outer edge of the recessed portion 12. When the coordinates of positions A, B, and C are determined, the coordinates of portions including the surface electrode 11 are determined as illustrated in FIG. 5. However, when the surface electrode 11 includes a layer of plating, the coordinates of portions excluding the layer of plating are determined.

FIG. 5 illustrates the connection terminal formed of the copper pillar bump. In the case of the connection terminal formed of a solder bump, the radius of curvature Rs may also be determined in the same way as described above.

In the electronic device according to the present invention, letting the radius of curvature of the recessed portion when viewed in cross section be Rs, and letting the radius of curvature of the connection terminal when viewed in cross section be Rp, the value of Rp/Rs is preferably 0.1 to 1.0. The value of Rp/Rs is more preferably 0.2 to 1.0.

In the electronic device according to the present invention, the maximum depth of the recessed portion excluding the layer of plating is preferably, but not necessarily, 3 μm to 20 μm.

In the electronic device according to the present invention, the structure of the surface electrode is not particularly limited as long as the surface electrode is disposed on at least part of the recessed portion. The surface electrode may be disposed on part of the recessed portion or may be disposed on the entire surface of the recessed portion. The surface electrode disposed on the recessed portion may be electrically connected to a surface electrode disposed on a surface of a portion other than the recessed portion.

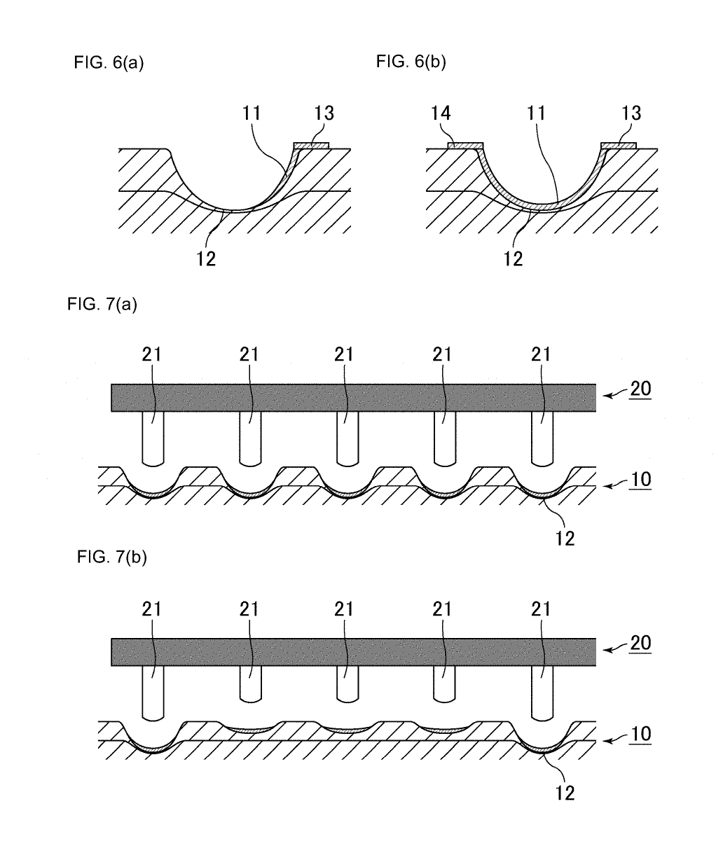

FIGS. 6(a) and 6(b) are schematic cross-sectional views illustrating examples of the surface electrode disposed on the recessed portion.

In FIG. 6(a), the surface electrode 11 disposed on part of the recessed portion 12 is electrically connected to a surface electrode 13 disposed on a surface of a portion other than the recessed portion 12. In FIG. 6(b), the surface electrode 11 disposed on the entire surface of the recessed portion 12 is electrically connected to the surface electrodes 13 and 14 disposed on surfaces of portions other than the recessed portion 12.

In the electronic device according to the present invention, in the case where the electronic component includes multiple connection terminals, the recessed portions need not be disposed at positions on the mounting surface of the multilayer ceramic substrate corresponding to all connection terminals. The recessed portion needs to be disposed at a position corresponding to at least one connection terminal.

FIGS. 7(a) and 7(b) are schematic cross-sectional views illustrating other examples of the electronic device according to the present invention. In FIGS. 7(a) and 7(b), for convenience, the electronic component 20 is illustrated in a state of being separated from the multilayer ceramic substrate 10.

As illustrated in FIG. 7(a), in the case where the electronic component 20 includes the connection terminals 21 having the same length, the recessed portions 12 having the same depth are preferably disposed at positions corresponding to all the connection terminals 21. As illustrated in FIG. 7(b), in the case where the electronic component 20 includes the connection terminals 21 having different lengths, the recessed portions 12 having different depths in accordance with the lengths of the connection terminals 21 are preferably disposed in such a manner that the electronic component 20 is not tilted with respect to the multilayer ceramic substrate 10. However, in FIG. 7(b), recessed portions need not necessarily be disposed at positions corresponding to the connection terminals having a short length.

The electronic device according to the present invention is preferably produced as described below.

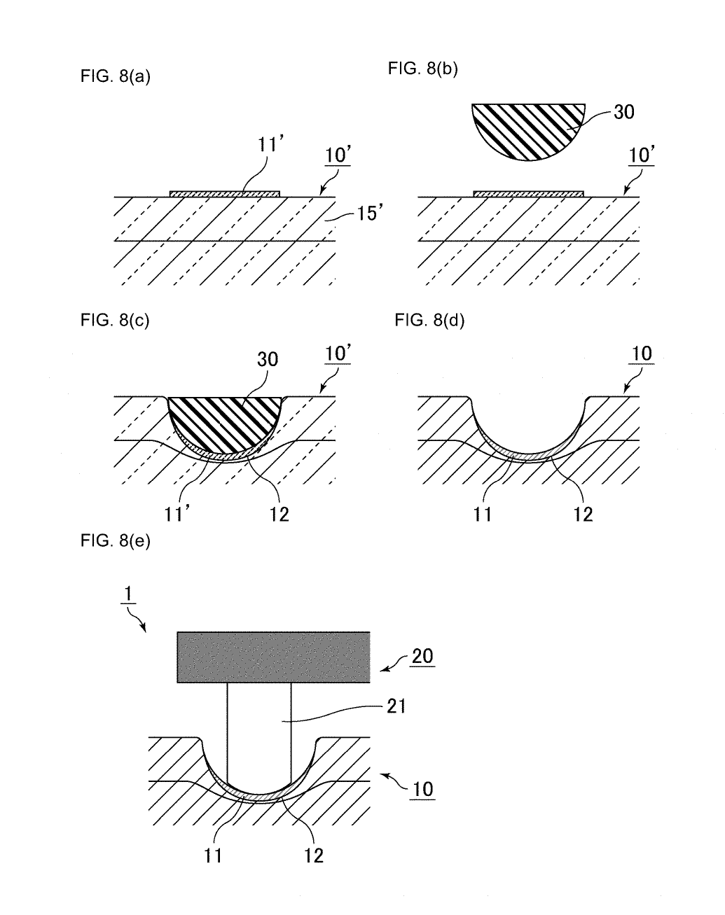

FIGS. 8(a), 8(b), 8(c), 8(d), and 8(e) are schematic cross-sectional views illustrating an example of a method for producing the electronic device illustrated in FIG. 1.

Multiple ceramic green sheets are provided. The ceramic green sheets will be fired to form ceramic layers.

The ceramic green sheets are obtained by forming a slurry containing a ceramic raw material powder such as a low-temperature co-fired ceramic material, an organic binder, and a solvent into sheets by, for example, a doctor blade method. The slurry may contain various additives such as a dispersant and a plasticizer.

A through-hole for a via conductor is formed in a specific ceramic green sheet. A conductive paste body to be formed into the via conductor is formed by filling the through-hole with a conductive paste containing, for example, silver or copper.

A conductive paste layer to be formed into an inner layer conductor is formed on a specific ceramic green sheet with a conductive paste having the same composition as the foregoing conductive paste by a method such as screen printing.

As illustrated in FIG. 8(a), a conductive paste layer 11′ to be formed into the surface electrode 11 is formed on a ceramic green sheet 15′ disposed on a surface after stacking. The conductive paste layer 11′ may be formed by a method such as screen printing with a conductive paste having the same composition as the foregoing conductive paste. Subsequently, the ceramic green sheets 15′ are stacked and subjected to pressure bonding to produce a green multilayer body 10′.

As illustrated in FIG. 8(b), a portion of the green multilayer body 10′ corresponding to the connection terminal of the electronic component is pressed with a metal die 30 having a predetermined shape. Thereby, as illustrated in FIG. 8(c), the recessed portion 12 having a rounded concave shape when viewed in cross section is formed on a surface of the green multilayer body 10′. In FIG. 8(c), the conductive paste layer 11′ is disposed on part of the recessed portion 12.

When the green multilayer body is pressed, the recessed portion having a desired shape can be formed by changing the shape of the metal die. The recessed portion may also be formed by, for example, drilling or laser processing.

After the metal die is removed, the green multilayer body 10′ is fired. Thereby, as illustrated in FIG. 8(d), a sintered body (multilayer ceramic substrate 10) including the surface electrode 11 on the surface of the recessed portion 12 is produced.

After firing, the sintered body may be subjected to electroplating or electroless plating to form a layer of plating on the upper surface of the surface electrode.

As illustrated in FIG. 8(e), the electronic component 20 including the connection terminal 21 having an end with a rounded convex shape when viewed in cross section on the mounting surface side of the electronic component is mounted on the multilayer ceramic substrate 10. Specifically, the connection terminal 21 of the electronic component 20 is brought into contact with the surface electrode 11 of the multilayer ceramic substrate 10 to electrically connect the surface electrode 11 to the connection terminal 21.

In this way, the electronic device 1 illustrated in FIG. 1 is produced.

After constraining green sheets containing an oxide that is not substantially sintered at the sintering temperature of the ceramic green sheets are provided, the multilayer body may be fired while the constraining green sheets are disposed on the respective main surfaces of the green multilayer body. A green multilayer composite including a constraining green sheet disposed between the ceramic green sheets may be fired. A green multilayer composite may be fired while constraining green sheets are disposed on the respective main surfaces of the green multilayer composite.

In such a case, the constraining green sheets are not substantially sintered during firing and do not shrink. Thus, the constraining green sheets serve to inhibit the shrinkage of the multilayer body or the multilayer composite in the main surface direction, thereby enhancing the dimensional accuracy of the multilayer ceramic substrate.

The constraining green sheets are preferably obtained by forming a slurry into sheets using, for example, a doctor blade method, the slurry containing the powder of the oxide, an organic binder, and a solvent. The slurry may contain various additives such as a dispersant and a plasticizer.

As the oxide contained in the slurry, for example, alumina, titania, zirconia, silica, or magnesia may be used. Among these, alumina is preferably used.

While the electronic device according to the present invention has been described above, the multilayer ceramic substrate included in the electronic device is also one of the embodiments of the present invention.

### EXAMPLES

The following will describe examples that specifically disclose an electronic device according to the present invention. The present invention is not limited to these examples.

### Example 1: Production of Multilayer Ceramic Substrate Including Recessed Portion Having Arc-Like Shape

(Step of Providing Ceramic Sheet 1)

A ceramic sheet 1 is a ceramic green sheet to be formed into a ceramic layer of a multilayer ceramic substrate.

As starting materials, SiO₂, BaCO₃, Al₂O₃, ZrO₂, CaCO₃, B₂O₃, MnCO₃, TiO₂, and Mg(OH)₂ were provided in powder form.

An organic binder, a dispersant, and a plasticizer were added to the powdery starting materials to prepare a ceramic slurry.

The ceramic slurry was formed into a sheet on a PET film by a doctor blade method and then dried to produce the ceramic sheet 1.

(Step of Providing Ceramic Sheet 2)

A ceramic sheet 2 is a constraining green sheet to be laminated in the multilayer ceramic substrate.

An alumina powder and a B—Si—Ba-based glass powder were weighed so as to have a predetermined composition ratio, mixed together, and pulverized. The preparation of a ceramic slurry and the production of the ceramic sheet 2 were performed in the same way as in the ceramic sheet 1.

(Step of Providing Ceramic Sheet 3)

A ceramic sheet 3 is a constraining green sheet to be disposed on a main surface of the multilayer ceramic substrate.

An alumina powder and a glass powder were weighed so as to have a predetermined composition ratio, mixed together, and pulverized. The preparation of a ceramic slurry and the production of the ceramic sheet 3 were performed in the same way as in the ceramic sheet 1.

(Step of Providing Conductive Paste)

A Cu powder, ethyl cellulose, and a terpene-based solvent were mixed, kneaded, and dispersed with a three-roll mill, thereby preparing a conductive paste for electrode formation.

(Step of Applying Conductive Paste to Ceramic Sheet by Printing)

The conductive paste was applied to the specified ceramic sheets 1, 2, and 3 by a screen printing method.

(Step of Stacking and Pressure-Bonding Ceramic Sheet)

Each of the ceramic sheets was cut into 100 mm×100 mm pieces. The pieces were pressure-bonded at a temperature of 50° C. or higher and 80° C. or lower and a pressure of 50 MPa or more and 200 MPa or less to produce a green multilayer composite. In this multilayer composite, the ceramic sheet 3, the ceramic sheet 1, and the ceramic sheet 2 were stacked in this order from a surface.

(Step of Forming Recessed Portion)

A portion of the green multilayer composite corresponding to the connection terminal of an electronic component was pressed with a metal die having an arc-like shape when viewed in cross section, thereby forming a recessed portion having an arc-like shape when viewed in cross section on a surface of the green multilayer composite. The recessed portion was formed in such a manner that the surface electrode after firing was disposed on part of the recessed portion. After the stacking of the ceramic sheet 2 and the ceramic sheet 1 in this order and then pressing with the metal die, the ceramic sheet 3 may be stacked and pressure-bonded.

(Step of Firing Green Multilayer Composite)

The green multilayer composite was heated to a firing temperature of 850° C. or higher and 1,050° C. or lower, held for 60 minutes or more and 90 minutes or less, and cooled to room temperature in a H₂/N₂/H₂O atmosphere while the atmosphere was adjusted so as not to oxidize Cu, thereby producing the multilayer ceramic substrate including the surface electrode on the recessed portion having arc-like shape. After the firing, the unsintered ceramic sheet 3 disposed on the surface of the multilayer ceramic substrate was removed by, for example, ultrasonic cleaning. A layer of plating was formed on the surface electrode on the surface of the multilayer ceramic substrate by electroplating or electroless plating.

### Example 2: Production of Multilayer Ceramic Substrate Including Recessed Portion Having Bathtub-Like Shape

A multilayer ceramic substrate was produced in the same way as in Example 1, except that the green multilayer composite was pressed with a metal die having a bathtub-like shape when viewed in cross section in place of the metal die having an arc-like shape when viewed in cross section to form a recessed portion having a bathtub-like shape when viewed in cross section on a surface of the green multilayer composite.

### Comparative Example 1: Production of Multilayer Ceramic Substrate Including Recessed Portion Having Rectangular Shape

A multilayer ceramic substrate was produced in the same way as in Example 1, except that the green multilayer composite was pressed with a metal die having a rectangular shape when viewed in cross section in place of the metal die having an arc-like shape when viewed in cross section to form a recessed portion having a rectangular shape when viewed in cross section on the surface of the green multilayer composite.

### Comparative Example 2: Production of Multilayer Ceramic Substrate with No Recessed Portion

A multilayer ceramic substrate was produced in the same way as in Example 1, except that the pressing of the green multilayer composite with the metal die was not performed and thus no recessed portion was formed on the surface of the green multilayer composite.

[Evaluation of Electronic Device]

Electronic components were mounted on the multilayer ceramic substrates of Examples 1 and 2 and Comparative examples 1 and 2 to produce electronic devices. To evaluate damage to the electronic components during mounting, defective contact was evaluated.

As the electronic components, ICs each having an internal conduction check pattern were provided, and bumps serving as connection terminals were attached to electrode portions of the ICs. As the bumps, solder bumps and copper pillar bumps were used.

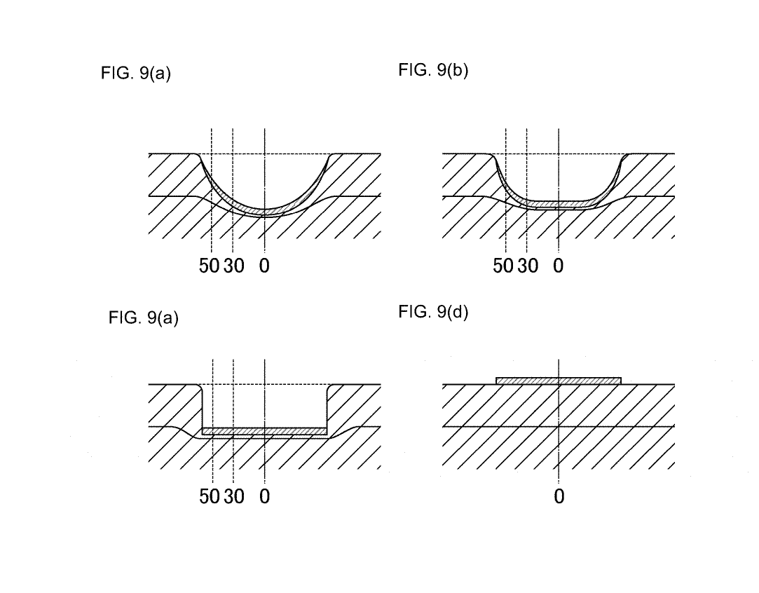

FIGS. 9(a), 9(b), 9(c), and 9(d) are schematic cross-sectional views illustrating positions where the electronic components are mounted on the multilayer ceramic substrates of Example 1, Example 2, Comparative example 1, and Comparative example 2, respectively.

As illustrated in FIG. 9(a), the IC was mounted on the surface electrode of the multilayer ceramic substrate of Example 1 disposed on the recessed portion having an arc-like shape at the center of the recessed portion (position expressed as 0 in FIG. 9(a)), a position 30 μm from the center (position expressed as 30 in FIG. 9(a)), or a position 50 μm from the center (position expressed as 50 in FIG. 9(a)). The defective contact was evaluated at the three positions 0 μm, 30 μm, and 50 μm from the center.

In the cases of the surface electrode of the multilayer ceramic substrate of Example 2 disposed on the recessed portion having a bathtub-like shape and the surface electrode of the multilayer ceramic substrate of Comparative example 1 disposed on the recessed portion having a rectangular shape, as illustrated in FIGS. 9(b) and 9(c), the defective contact was evaluated at the three positions 0 μm, 30 μm, and 50 μm from the center. In the case of the surface electrode of the multilayer ceramic substrate of Comparative example 2, in which no recessed portion was disposed, as illustrated in FIG. 9(d), the IC was mounted on the center of the surface electrode (position expressed as 0 in FIG. 9(d)), and the defective contact was evaluated at the one position 0 μm from the center.

Table 1 presents the evaluation results of the defective contact. In Table 1, the case where no defective contact occurred was denoted as ◯, and the case where the defective contact occurred was denoted as x.

The recessed portion had a width of 120 μm and a maximum depth of 10 μm or more and 30 μm or less. The evaluation was performed at a constant radius of curvature of the connection terminal (bump). In the case where the recessed portion was disposed, the evaluation was performed at a constant ratio of the radius of curvature Rp of the connection terminal to the radius of curvature Rs of the recessed portion (Rp/Rs). Regarding the recessed portion having a bathtub-like shape, the radius of curvature of the recessed portion at a position 50 μm from the center was defined as the radius of curvature Rs.

TABLE 1

| | | | Evaluation of | | |
|---|---|---|---|---|---|
| | Recessed | | defective contact | | |
| | portion | Bump | 0 μm | 30 μm | 50 μm |
| Example 1 | arc-like | solder | ∘ | ∘ | ∘ |
| | shape | copper pillar | ∘ | ∘ | ∘ |
| Example 2 | bathtub-like | solder | x | x | ∘ |
| | shape | copper pillar | x | x | ∘ |
| Comparative | rectangular | solder | x | x | x |
| example 1 | shape | copper pillar | x | x | x |
| Comparative | no | solder | x | — | — |
| example 2 | | copper pillar | x | — | — |

Table 1 indicates that in each of Comparative example 1 in which the recessed portion having a rectangular shape was disposed and Comparative example 2 in which no recessed portion was disposed, the defective contact occurred presumably because the connection terminal and the surface electrode were in point contact with each other. In contrast, in Example 1 in which the recessed portion having an arc-like shape was disposed, no defective contact occurred presumably because the connection terminal and the surface electrode were in surface contact with each other. In Example 2 in which the recessed portion having a bathtub-like shape was disposed, at the position 50 μm from the center, no defective contact occurred presumably because the connection terminal and the surface electrode were in surface contact.

Regarding each of the multilayer ceramic substrates of Examples 1 and 2, the defective contact was evaluated when the value of Rp/Rs at the position 50 μm from the center was changed to a value within a range presented in Table 2. Table 2 presents the evaluation results of the defective contact. In Table 2, the case where the number of occurrence of the defective contact was zero was evaluated as ⊙ (excellent), the case where the number of occurrence of the defective contact was 1 or more and 10 or less was evaluated as ◯ (good), the case where the number of occurrence of the defective contact was 11 or more and 50 or less was evaluated as Δ (fair), the case where the number of occurrence of the defective contact was 51 or more was evaluated as x (poor), per 1,000 ICs.

TABLE 2

| | | | Evaluation of defective contact | | | | |
|---|---|---|---|---|---|---|---|
| | Recessed | | Ratio of radius of curvature Rp/Rs | | | | |
| | portion | Bump | 0.05 | 0.1 | 0.2 | 0.5 | 1.0 |
| Example | arc-like | solder | Δ | ◯ | ⊙ | ⊙ | ⊙ |
| 1 | shape | copper | Δ | ◯ | ⊙ | ⊙ | ⊙ |
| | | pillar | | | | | |
| Example | bathtub-like | solder | Δ | ◯ | ⊙ | ⊙ | ⊙ |
| 2 | shape | copper | Δ | ◯ | ⊙ | ⊙ | ⊙ |
| | | pillar | | | | | |

Table 2 indicates that in Example 1 in which the recessed portion having an arc-like shape was disposed, the occurrence of the defective contact was reduced when the value of Rp/Rs was 0.1 or more and 1.0 or less, and the occurrence of the defective contact was particularly reduced when the value of Rp/Rs was 0.2 or more and 1.0 or less.

In Example 2 in which the recessed portion having a bathtub-like shape was disposed, the occurrence of the defective contact was reduced when the value of Rp/Rs was 0.1 to 1.0, and the occurrence of the defective contact was particularly reduced when the value of Rp/Rs was 0.2 to 1.0.

### REFERENCE SIGNS LIST

1 electronic device
10 multilayer ceramic substrate
11, 13, 14 surface electrode
12 recessed portion
20 electronic component
21 connection terminal
22 copper pillar bump (connection terminal)
23 solder bump (connection terminal)

1. An electronic device, comprising:
an electronic component including a connection terminal on a mounting surface side thereof, the connection terminal having an end with a rounded convex shape when viewed in cross section; and
a multilayer ceramic substrate including:
a recessed portion at a position corresponding to the connection terminal, the recessed portion having a rounded concave shape when viewed in cross section, and
a surface electrode disposed on at least part of the recessed portion and electrically connected to the connection terminal.

2. The electronic device according to claim 1, wherein the recessed portion has an arc- or bathtub-like shape in cross section.

3. The electronic device according to claim 2, wherein Rp/Rs is 0.1 to 1.0, where Rs is a radius of curvature of the recessed portion when viewed in cross section, and Rp is a radius of curvature of the connection terminal when viewed in cross section.

4. The electronic device according to claim 2, wherein Rp/Rs is 0.2 to 1.0, where Rs is a radius of curvature of the recessed portion when viewed in cross section, and Rp is a radius of curvature of the connection terminal when viewed in cross section.

5. The electronic device according to claim 1, wherein Rp/Rs is 0.1 to 1.0, where Rs is a radius of curvature of the recessed portion when viewed in cross section, and Rp is a radius of curvature of the connection terminal when viewed in cross section.

6. The electronic device according to claim 1, wherein Rp/Rs is 0.2 to 1.0, where Rs is a radius of curvature of the recessed portion when viewed in cross section, and Rp is a radius of curvature of the connection terminal when viewed in cross section.

7. The electronic device according to claim 1, wherein a depth of the recessed portion is 3 μm to 20 μm.

8. The electronic device according to claim 1, wherein the electronic component includes a plurality of connection terminals having a same length, and the multilayer ceramic substrate includes a plurality of recessed portions having a same depth at positions corresponding to the plurality of connection terminals.

9. The electronic device according to claim 1, wherein the electronic component includes a plurality of connection terminals having different lengths, and the multilayer ceramic substrate includes a plurality of recessed portions having different depths in accordance with the different lengths of the plurality of connection terminals at positions corresponding to the plurality of connection terminals.

10. A multilayer ceramic substrate on which an electronic component is to be mounted, the multilayer ceramic substrate comprising:
a recessed portion having a rounded concave shape when viewed in cross section; and
a surface electrode disposed on at least part of the recessed portion.

11. The multilayer ceramic substrate according to claim 10, wherein the recessed portion has an arc- or bathtub-like shape in cross section.

12. The multilayer ceramic substrate according to claim 10, wherein a depth of the recessed portion is 3 μm to 20 μm.

13. The multilayer ceramic substrate according to claim 10, wherein the multilayer ceramic substrate includes a plurality of recessed portions having a same depth.

14. The multilayer ceramic substrate according to claim 10, wherein the multilayer ceramic substrate includes a plurality of recessed portions having different depths.
